(19) United States
(12) Patent Application Publication
(10) Pub. No.: US 2017/0103900 A1
(43) Pub. Date: Apr. 13, 2017

(54) METHOD FOR FORMING WAFER

(71) Applicant: ZING SEMICONDUCTOR CORPORATION, Shanghai (CN)

(72) Inventors: DEYUAN XIAO, Shanghai (CN); RICHARD R. CHANG, Shanghai (CN)

(21) Appl. No.: 15/178,041

(22) Filed: Jun. 9, 2016

(30) Foreign Application Priority Data
Oct. 13, 2015 (CN) 201510659200.2

(51) Int. Cl. H01L 21/30; B24B 9/06; B24B 7/22

(52) U.S. Cl. CPC H01L 21/3003; B24B 7/228; B24B 9/065

(57) ABSTRACT

This invention provides a method for forming a wafer comprising forming a silicon substrate, and then performing rapid thermal annealing to the substrate to form a passivation layer. The passivation layer reduces the surface roughness of the silicon substrate. During the formation of a gate oxide layer or an interface, deuterium can diffuse from the substrate and combine with dangling bonds of the interface to form a stable structure, thereby carrier penetration can be prevented and device properties can be enhanced.

### BACKGROUND OF THE INVENTION

1. Field of the Invention

The present application relates to a semiconductor manufacture, and more particularly to a method of formation of a wafer.

2. Description of the Related Art

Monocrystalline silicon is the initial material in the semiconductor manufacture, which is generally formed by Czochralski (CZ) method.

Challenges for the quality of the silicon substrate are increasing with the tendency of size reduction of microelectronic devices. The quality of the silicon substrate depends on size and distribution of microdefects grown therein. During the formation of the silicon substrate by CZ method or float zone method, most of the microdefects clusters among the silicon-vacancies or fills within the spaces.

Hydrogen passivation has become a well-known and established practice in the fabrication of semiconductor devices. In the hydrogen passivation process, defects which affect the operation of semiconductor devices are removed. For example, such defects have been described as recombination/generation centers on active components of semiconductor devices. These centers are thought to be caused by dangling bonds which introduce states in the energy gap which remove charged carriers or add unwanted charge carriers in the device, depending in part on the applied bias. While dangling bonds occur primarily at surfaces or interfaces in the device, they also are thought to occur at vacancies, micropores, dislocations, and also to be associated with impurities.

Another problem which has arisen in the semiconductor industry is the degradation of device performance by hot carrier effects. This is particularly of concern with respect to smaller devices in which proportionally larger voltages are used. When such high voltages are used, channel carriers can be sufficiently energetic to enter an insulating layer and degrade device behavior.

Since hydrogen passivation is not stable enough, its bonding with the dangling bond is broken easily. Therefore, the dangling bond is exposed again to adversely affect the properties of the device.

### SUMMARY

The present application is to provide a method for forming a wafer, in which the method is able to reduce the surface roughness of the wafer, reduce the dangling bonds of the interface in the device, and enhance the device properties.

For above, the present application provides a method for forming a wafer comprising providing a silicon substrate, performing rapid thermal annealing to the silicon substrate to form a passivation layer, wherein the rapid thermal annealing comprises using a gas containing deuterium.

Further, in the above method, the rapid thermal annealing is performed under a temperature of 1200° C.-1380° C.

Further, in the above method, the gas used in the rapid thermal annealing is a mixture of deuterium and hydrogen.

Further, in the above method, the deuterium is 1%-100% of the gas.

Further, in the above method, the gas used in the rapid thermal annealing is a mixture of deuterium and oxygen.

Further, in the above method, the deuterium is 1%-100% of the gas.

Further, in the above method, the gas used in the rapid thermal annealing is deuterium.

Further, in the above method, the silicon substrate is formed by the steps comprising: forming an silicon ingot, slicing, surface grinding, polishing, edge profiling and cleaning the silicon ingot, and forming the silicon substrate.

Further, in the above method, the silicon substrate is monocrystalline silicon.

Further, in the above method, the silicon substrate is formed by Czochralski (CZ) method.

The method of the present application is advantageous over the prior art. After forming the silicon substrate, the rapid thermal annealing is performed to the substrate to form the passivation layer. The passivation layer is able to reduce the surface roughness of the silicon substrate. Further, during the formation of a gate oxide layer or an interface, deuterium can diffuse from the substrate and combine with dangling bonds of the interface to form a stable structure, thereby the carrier penetration can be prevented and the device properties can be enhanced.

### BRIEF DESCRIPTION OF THE DRAWINGS

FIG. 1 shows one embodiment of the method for forming the wafer.

### DETAILED DESCRIPTION OF THE EMBODIMENTS

Although the following with reference to the accompanying drawings of the method of the present invention is further described in more detail, there is shown a preferred embodiment of the present invention. A person having ordinary skills in the art may modify the invention described herein while still achieving the advantageous effects of the present invention. Thus, these embodiments should be understood as broad teaching one skilled in the art, and not as a limitation of the present invention.

For purpose of clarity, not all features of an actual embodiment are described. It may not describe the well-known functions as well as structures in detail to avoid confusion caused by unnecessary details. It should be considered that, in the developments of any actual embodiment, a large number of practice details must be made to achieve the specific goals of the developer, for example, according to the requirements or the constraints of the system or the commercials, one embodiment is changed to another. In addition, it should be considered that such a development effort might be complex and time-consuming, but for a person having ordinary skills in the art is merely routine work.

In the following paragraphs, the accompanying drawings are referred to describe the present invention more specifically by way of example. The advantages and the features of the present invention are more apparent according to the following description and claims. It should be noted that the drawings are in a simplified form with non-precise ratio for the purpose of assistance to conveniently and clearly explain an embodiment of the present invention.

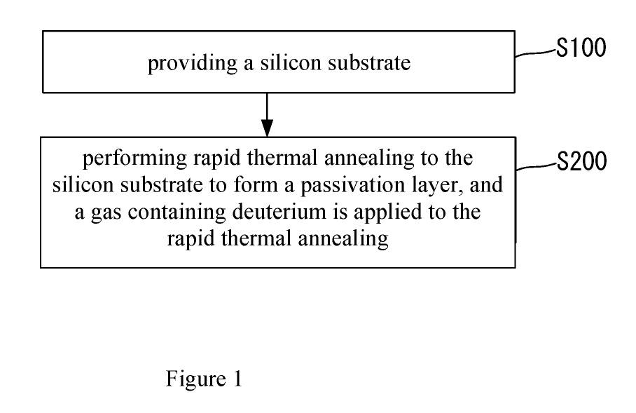

In one embodiment, referring to FIG. 1, the method for forming the wafer comprises the following steps:

S100: providing a silicon substrate,
S200: performing rapid thermal annealing to the silicon substrate to form a passivation layer, and the rapid thermal annealing comprising using a gas containing deuterium.

In one embodiment, the silicon substrate can be formed by the following steps. First, an silicon ingot is formed and polished to a desired size such as the size of wafer. Then the steps including slicing, surface grinding, polishing, edge profiling and cleaning are applied to form the silicon substrate. In the present embodiment, the silicon substrate is monocrystalline silicon formed by Czochralski (CZ) method.

In S200, the rapid thermal annealing is performed to the silicon substrate to form a passivation layer. The formation of the passivation layer is able to reduce the surface roughness of the silicon substrate and enhance the properties of the silicon substrate.

In one embodiment, the temperature of the rapid thermal annealing can be between 1200° C.-1380° C., such as 1300° C.

In one embodiment, the gas used in the rapid thermal annealing is a mixture of deuterium and hydrogen. The deuterium is 1%-100% of the gas mixture, which can be adjusted according to different process requirements.

In one embodiment, a mixture of deuterium and oxygen can be applied. The deuterium is 1%-100% of the gas mixture, which can be adjusted according to different process requirements.

In one embodiment, the pure deuterium can be applied to the rapid thermal annealing.

While deuterium is applied to the rapid thermal annealing, deuterium is able to be temporarily stored in the gap of the silicon substrate because of the small size of the deuterium atom. In the following process for forming the gate oxide layer, the stored deuterium atoms can combine to dangling bonds of the gate oxide layer to form stable chemical bonds. Accordingly, the redundant dangling bonds can be eliminated, and the properties of the gate oxide layer can be enhanced thereby. Moreover, the deuterium atoms not only combine to the dangling bonds of the gate oxide layer but also the dangling bonds of other layers of the semiconductor device. The formed chemical bond from deuterium is more stable than that from other elements such as hydrogen atom.

According to the above, in the examples of the method of the present application, the rapid thermal annealing is performed to the silicon substrate to form a passivation layer after formation of the silicon substrate. The passivation layer is able to reduce the surface roughness of the silicon substrate. During the formation of the gate oxide layer or the interface, deuterium can diffuse from the substrate and combine with dangling bonds of the interface to form a stable structure, thereby the carrier penetration can be prevented and the device properties can be enhanced.

Realizations of the above method have been described in the context of particular embodiments. These embodiments are meant to be illustrative and not limiting. Many variations, modifications, additions, and improvements are possible. These and other variations, modifications, additions, and improvements may fall within the scope of the invention as defined in the claims that follow.

1. A method for forming a wafer comprising:
providing a silicon substrate,
performing rapid thermal annealing to the silicon substrate to form a passivation layer, wherein the rapid thermal annealing comprises using a gas containing deuterium.

2. The method of claim 1, wherein the rapid thermal annealing is performed under a temperature of 1200° C.-1380° C.

3. The method of claim 1, wherein the gas used in the rapid thermal annealing is a mixture of deuterium and hydrogen.

4. The method of claim 3, wherein the deuterium is 1%-100% of the gas.

5. The method of claim 1, wherein the gas used in the rapid thermal annealing is a mixture of deuterium and oxygen.

6. The method of claim 5, wherein the deuterium is 1%-100% of the gas.

7. The method of claim 1, wherein the gas used in the rapid thermal annealing is deuterium.

8. The method of claim 1, wherein the silicon substrate is formed by the steps comprising:
forming an silicon ingot,
slicing, surface grinding, polishing, edge profiling and cleaning the silicon ingot, and
forming the silicon substrate.

9. The method of claim 1, wherein the silicon substrate is monocrystalline silicon.

10. The method of claim 8, wherein the silicon substrate is formed by Czochralski (CZ) method.
